(19) United States
(12) Patent Application Publication
(10) Pub. No.: US 2025/0351749 A1
(43) Pub. Date: Nov. 13, 2025

(54) SEMICONDUCTOR MEMORY DEVICE AND METHOD FOR MANUFACTURING THE SAME

(71) Applicant: TAIWAN SEMICONDUCTOR MANUFACTURING COMPANY, LTD., Hsinchu (TW)

(72) Inventors: Tzu-Yu CHEN, Hsinchu (TW); Fu-Chen CHANG, Hsinchu (TW); Sheng-Hung SHIH, Hsinchu (TW); Kuo-Chi TU, Hsinchu (TW); Wen-Ting CHU, Hsinchu (TW)

(73) Assignee: TAIWAN SEMICONDUCTOR MANUFACTURING COMPANY, LTD., Hsinchu (TW)

(21) Appl. No.: 18/662,622

(22) Filed: May 13, 2024

(51) Int. Cl. H10N 70/00; H10B 63/00; H10N 70/20

(52) U.S. Cl. CPC H10N 70/841; H10B 63/00; H10N 70/063; H10N 70/24; H10N 70/8265

(57) ABSTRACT

A semiconductor memory device includes a dielectric layer, a metal line, a bottom electrode, a high-k dielectric portion, and a top electrode. The metal line is disposed in the dielectric layer. The bottom electrode is disposed on and electrically connected to the metal line. The high-k dielectric portion is disposed on the bottom electrode opposite to the dielectric layer. The top electrode is disposed on the high-k dielectric portion opposite to the bottom electrode. One of the bottom electrode and the top electrode includes an inert metal, an alloy of the inert metal, a combination of the inert metal and an active metallic material, or a combination of the alloy of the inert metal and the active metallic material, and the other one of the bottom electrode and the top electrode includes the active metallic material.

### BACKGROUND

Semiconductor memory devices (e.g., resistive random-access memory (RRAM) devices) have potentials to be applied in various fields. Recently, there is an increased demand of the semiconductor memory devices, which puts more stringent requirements on device performance of the semiconductor memory devices. In order to meet the increased demand and more stringent requirements on device performance, the semiconductor industry continuously strives to improve device performance of the semiconductor memory devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are flow diagrams illustrating a method for manufacturing a semiconductor memory device in accordance with some embodiments.

FIGS. 2 to 17 are schematic views illustrating some intermediate stages of the method as depicted in FIGS. 1A and 1B in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “top,” “bottom,” “upper,” “lower,” “topmost,” “bottommost,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

Resistive random-access memory (RRAM) devices are promising candidates for next generation semiconductor memory devices due to various advantages, such as fast write speed, low power consumption, and ability to be scaled down. In order to meet more stringent requirements on device performance for next generation semiconductor memory devices, several shortcomings of the RRAM devices, such as high forming voltage (V_{f}), need to be overcome. By reducing a thickness of a high-dielectric constant (high-k) layer of a RRAM device, the forming voltage (V_{f}) of the RRAM device may be decreased, but device performance of the RRAM device may be adversely affected. Therefore, there is a need to find an alternative way to decrease the forming voltage (V_{f}) of the RRAM device without compromising the device performance thereof.

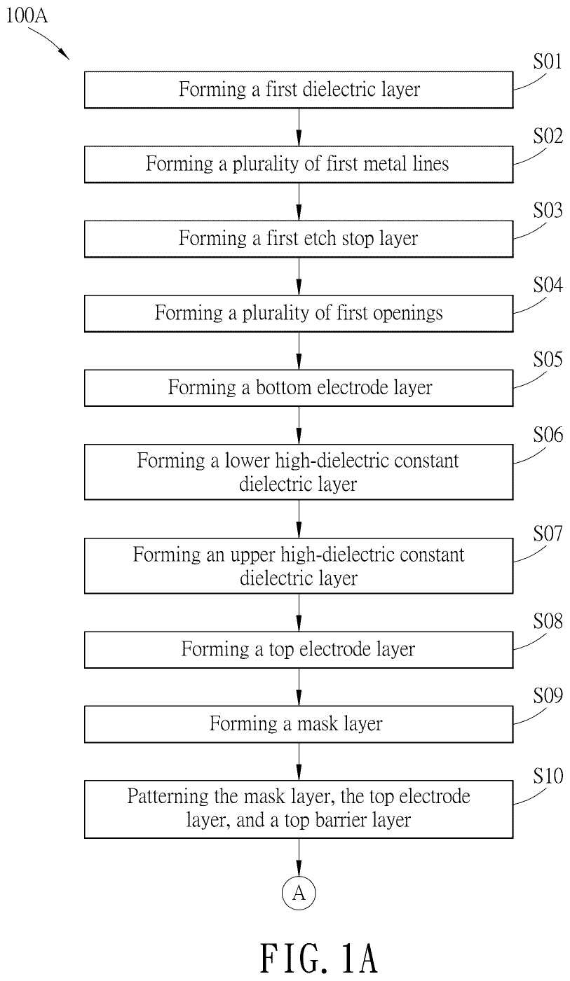

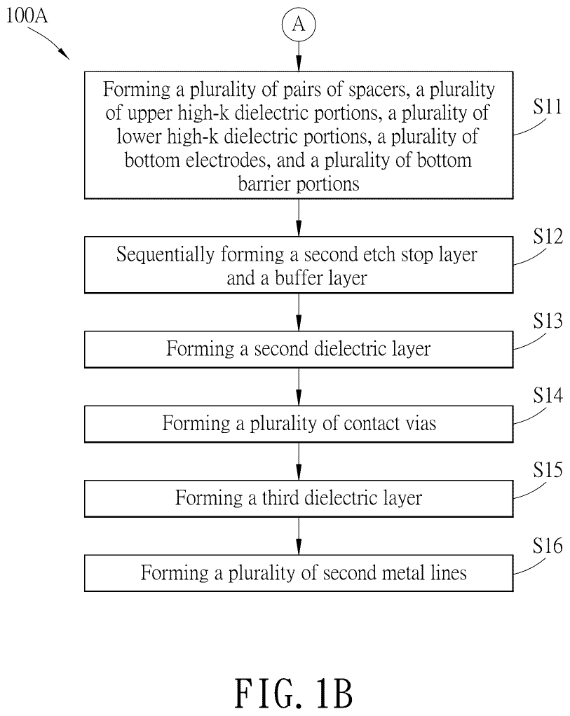

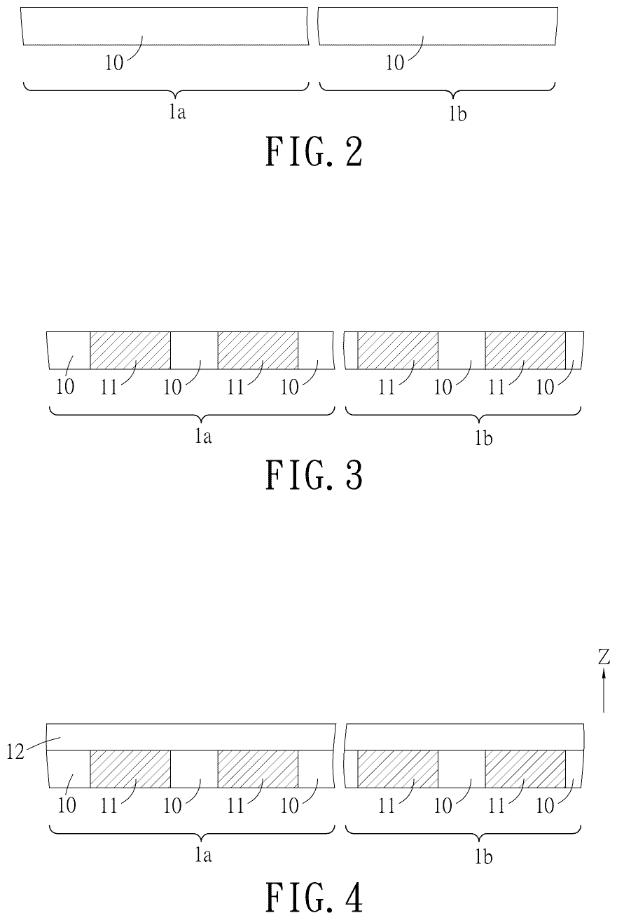

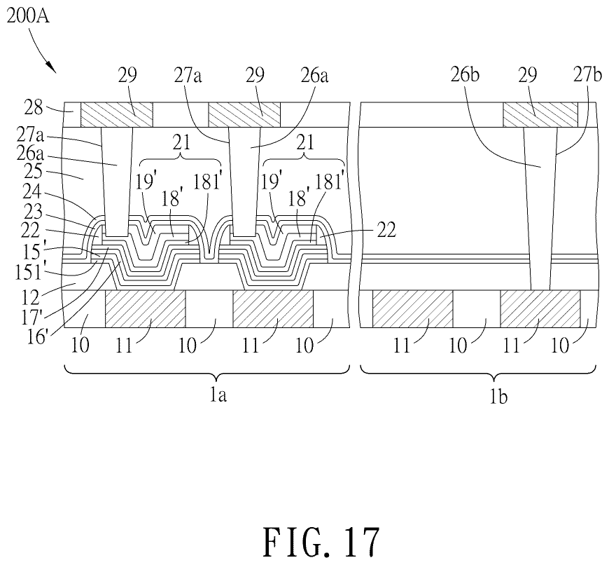

The present disclosure is directed to a semiconductor memory device and a method for manufacturing the same. FIGS. 1A and 1B are flow diagrams illustrating a method 100A for manufacturing a semiconductor memory device 200A shown in FIG. 17 in accordance with some embodiments. FIGS. 2 to 16 illustrate schematic views of some intermediate stages of the method 100A. Some portions may be omitted in FIGS. 2 to 16 for the sake of brevity. Additional steps can be provided before, after or during the method 100A, and some of the steps described herein may be replaced by other steps or be eliminated.

Referring to FIG. 1A and the example illustrated in FIG. 2, the method 100A begins at step S01, where a first dielectric layer 10 is formed. In some embodiments, the first dielectric layer 10 is formed on a topmost dielectric layer of an interconnect structure (not shown) disposed on a semiconductor substrate (not shown). In some embodiments, the interconnect structure includes a plurality of contact vias (not shown) that are disposed in the topmost dielectric layer and that are spaced apart from each other. In some embodiments, the first dielectric layer 10 may include, for example, but not limited to, silicon oxide, silicon nitride, silicon carbide, silicon oxycarbide, silicon oxynitride, silicon carbonitride, silicon oxycarbonitride, undoped silicate glass (USG), phosphosilicate glass (PSG), borosilicate glass (BSG), boron-doped phosphosilicate glass (BPSG), fluorine-doped silicate glass (FSG), or combinations thereof. In some alternative embodiments, the first dielectric layer 10 may include, for example, but not limited to, polyimide, epoxy resin, acrylic resin, phenol resin, benzocyclobutene (BCB), polybenzooxazole (PBO), other suitable polymer-based dielectric materials, or combinations thereof. Other suitable materials for the first dielectric layer 10 are within the contemplated scope of the present disclosure. The first dielectric layer 10 may be formed by a suitable deposition process, for example, but not limited to, chemical vapor deposition (CVD), physical vapor deposition (PVD), or other suitable deposition processes. In some embodiments, the first dielectric layer 10 may include a device memory region 1a and a device peripheral region 1b. In some embodiments, the first dielectric layer 10 may be an interlayer dielectric (ILD) layer.

Referring to FIG. 1A and the example illustrated in FIG. 3, the method 100A then proceeds to step S02, where a plurality of first metal lines 11 are formed in the first dielectric layer 10. Step S02 may include sub-step (i) patterning the first dielectric layer 10 to form a plurality of recesses (not shown), sub-step (ii) depositing a metallic material on the first dielectric layer 10 to fill the recesses, and sub-step (iii) removing an excess portion of the metallic material on the first dielectric layer 10, so as to form the first metal lines 11.

In sub-step (i), the first dielectric layer 10 may be patterned by photolithography, which includes an etching process. The photolithography may include, for example, but not limited to, coating a photoresist on the first dielectric layer 10, soft-baking the photoresist, exposing the photoresist through a photomask, post-exposure baking the photoresist, and developing the photoresist, followed by hard-baking the photoresist so as to form a patterned photoresist on the first dielectric layer 10. In the etching process, the first dielectric layer 10 may be etched by a suitable etching process (for example, but not limited to, dry etching, wet etching, a combination thereof, or other suitable etching processes) using the patterned photoresist as a patterned mask, so as to form the recesses. The patterned photoresist is removed by, for example, but not limited to, an ashing process or other suitable removal processes after the first dielectric layer 10 is formed with the recesses.

In sub-step (ii), the metallic material may be deposited on the first dielectric layer 10 to fill the recesses by a suitable deposition process, for example, but not limited to, CVD, PVD, electroless plating, electroplating, or other suitable deposition processes.

In sub-step (iii), removal of the excess portion of the metallic material on the first dielectric layer 10 may be performed by a suitable planarization process, for example, but not limited to, chemical mechanical polishing (CMP) or other suitable planarization processes. The metallic material for forming the first metal lines 11 may include, for example, but not limited to, copper, aluminum, tungsten, or combinations thereof. Other suitable materials for the first metal lines 11 are within the contemplated scope of the present disclosure.

In some embodiments, one or more of the first metal lines 11 are in contact with corresponding one(s) of the contact vias of the interconnect structure, respectively.

Referring to FIG. 1A and the example illustrated in FIG. 4, the method 100A then proceeds to step S03, where a first etch stop layer 12 is formed on the first dielectric layer 10 and the first metal lines 11 in a Z direction normal to the first dielectric layer 10. The first etch stop layer 12 may include, for example, but not limited to, metal nitride, metal oxide, metal carbide, silicon nitride, silicon oxide, silicon carbide, silicon oxynitride, or combinations thereof. Other suitable materials for the first etch stop layer 12 are within the contemplated scope of the present disclosure. The first etch stop layer 12 may be formed by a suitable deposition process, for example, but not limited to, CVD, plasma-enhanced CVD (PECVD), atomic layer deposition (ALD), spin-on coating, electroless plating, or other suitable deposition processes. In some embodiments, in this step, after formation of the first etch stop layer 12, a top surface of the first etch stop layer 12 may be planarized by a suitable planarization process (e.g., CMP or other suitable planarization processes).

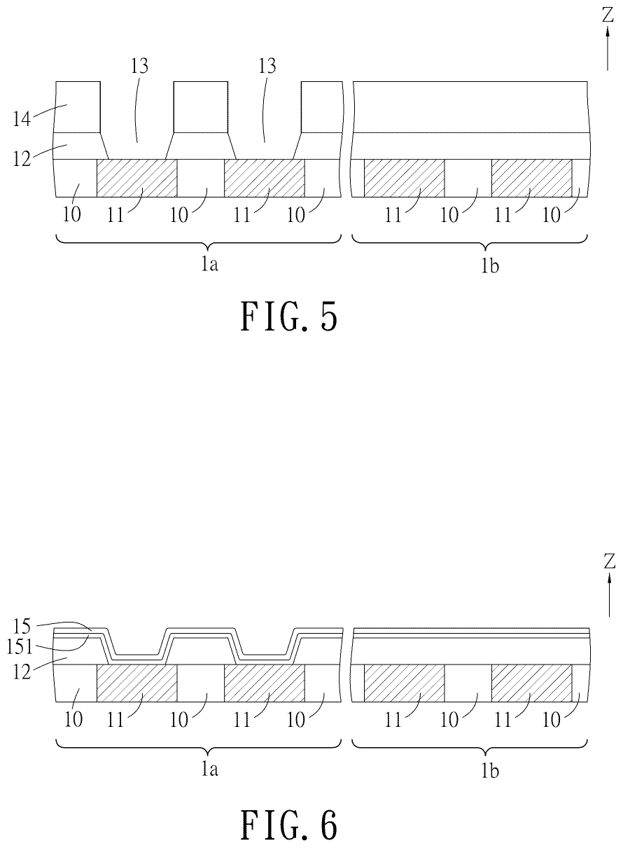

Referring to FIG. 1A and the example illustrated in FIG. 5, the method 100A then proceeds to step S04, where a plurality of first openings 13 are formed in the first etch stop layer 12 in the device memory region 1a, so as to expose the first metal lines 11 in the device memory region 1a. Step S04 may be performed by patterning the first etch stop layer 12 using a patterned photoresist layer 14 so as to form the first openings 13. The patterning process may be the photolithography process as described above in step S02, and details thereof are omitted for the sake of brevity. After this step, the patterned photoresist layer 14 is removed by, for example, but not limited to, an ashing process or other suitable removal processes. In some embodiments, each of the first openings 13 has a dimension decreasing gradually in a direction from an upper surface of the first etch stop layer 12 to a lower surface of the first etch stop layer 12.

Referring to FIG. 1A and the example illustrated in FIG. 6, the method 100A then proceeds to step S05, where a bottom electrode layer 15 is conformally formed on the first etch stop layer 12 and the first metal lines 11 in the device memory region 1a. Step S05 may be performed by a suitable deposition process, for example, but not limited to, CVD, metal-organic CVD (MOCVD), PVD, ALD, or other suitable deposition processes. The bottom electrode layer 15 is electrically connected to the first metal lines 11 in the device memory region 1a. In some embodiments, the bottom electrode layer 15 may be formed as a single layer structure or a multi-layered structure.

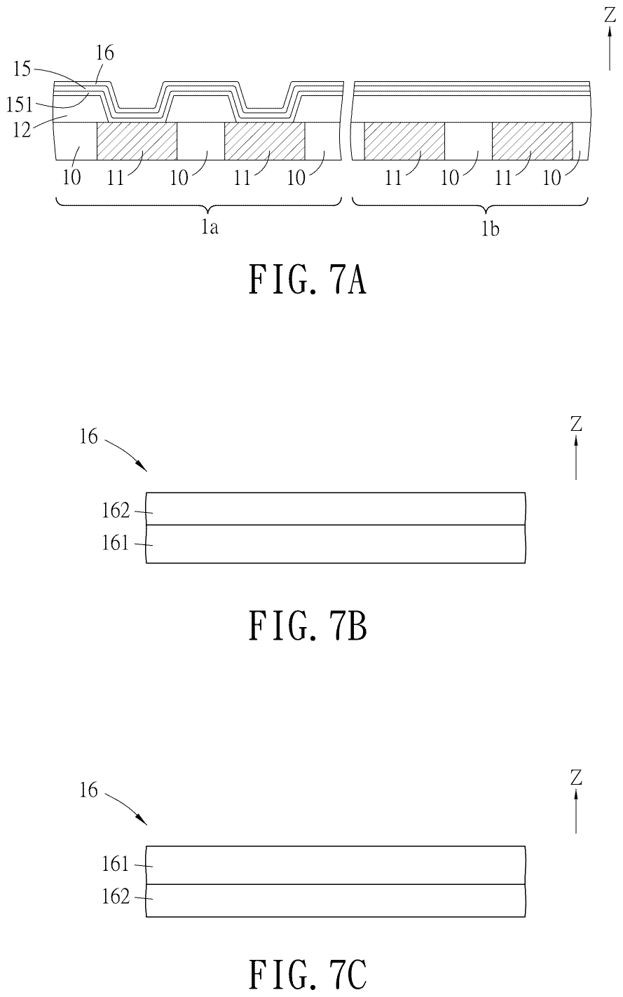

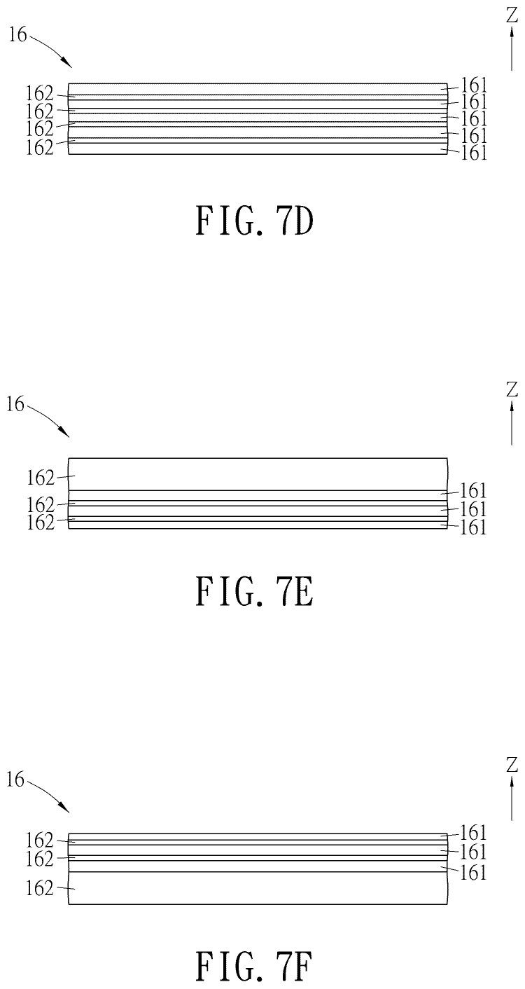

In a case that the bottom electrode layer 15 is formed as a single layer structure, the bottom electrode layer 15 may include, for example, but not limited to, an inert metal, an alloy of the inert metal, or an active metallic material. In some embodiments, the bottom electrode layer 15 is made of the inert metal, the alloy of the inert metal, or the active metallic material. In some embodiments, the inert metal may be, for example, but not limited to, palladium, platinum, darmstadtium, ruthenium, molybdenum, or iridium. In some embodiments, the active metallic material may be, for example, but not limited to, tantalum nitride, titanium nitride, tantalum, titanium, tungsten, aluminum, nickel, hafnium, lanthanum, zirconium, or combinations thereof. When the bottom electrode layer 15 includes the inert metal or the alloy of the inert metal, the bottom electrode layer 15 may have a thickness ranging from about 20 Å to about 350 Å. If the thickness of the bottom electrode layer 15 is less than about 20 Å, metal atoms of other layers (e.g., a lower high-dielectric constant (high-k) dielectric layer 16 shown in FIG. 7A) may diffuse into the bottom electrode layer 15, which may adversely affect the properties of the bottom electrode layer 15. If the thickness of the bottom electrode layer 15 is greater than about 350 Å, a total thickness of the semiconductor memory device 200A may be increased, which is not conducive to scaling down of the size of the semiconductor memory device 200A.

In a case that the bottom electrode layer 15 is formed as a multi-layered structure, the bottom electrode layer 15 may include an inert metal sublayer (not shown) and an active metal sublayer (not shown). In some embodiments, the inert metal sublayer is made of the inert metal or the alloy of the inert metal, which is described in the foregoing. In some embodiments, the inert metal sublayer may have a thickness ranging from about 20 Å to about 350 Å. In some embodiments, the active metal sublayer is made of the active metallic material, which is described in the foregoing. In some embodiments, the active metal sublayer may have a thickness ranging from about 0 Å to about 30 Å. If the thickness of the active metal sublayer is greater than about 30 Å, an amount of metal atoms in the active metal sublayer may be excessive, which may adversely affect the device performance of the semiconductor memory device 200A. In some embodiments, the active metal sublayer of the bottom electrode layer 15 is proximate to the lower high-k dielectric layer 16 relative to the inert metal sublayer of the bottom electrode layer 15.

As shown in FIG. 6, in some embodiments, before formation of the bottom electrode layer 15, a bottom barrier layer 151 is conformally formed on the first etch stop layer 12 and the first metal lines 11 in the device memory region 1a. The bottom barrier layer 151 may be formed by a suitable deposition process, for example, but not limited to, CVD, PVD, ALD, or other suitable deposition processes. The bottom barrier layer 151 may include, for example, but not limited to, titanium nitride, platinum, aluminum copper, gold, titanium, tantalum, tantalum nitride, tungsten, tungsten nitride, or combinations thereof. Other suitable materials for the bottom barrier layer 151 are within the contemplated scope of the present disclosure. In some embodiments, the bottom barrier layer 151 and the bottom electrode layer 15 are made of different materials. In some embodiments, the bottom barrier layer 151 may be a sublayer (e.g., a bottommost sublayer) of the bottom electrode layer 15 when the bottom electrode layer 15 is formed as a multi-layered structure.

Referring to FIG. 1A and the example illustrated in FIGS. 7A to 7F, the method 100A then proceeds to step S06, where the lower high-k dielectric layer 16 is conformally formed on the structure shown in FIG. 6. FIGS. 7B to 7F are schematic enlarged views respectively illustrating various configurations of the lower high-k dielectric layer 16 shown in FIG. 7A. Step S06 may be performed by a suitable deposition process, for example, but not limited to, CVD, PVD, ALD, plasma-enhanced ALD, molecular beam epitaxy (MBE), or other suitable deposition processes. In some embodiments, the lower high-k dielectric layer 16 may include, a metal oxide or a metal oxide doped with at least one metal element different from metal element(s) of the metal oxide. In some embodiments, the metal oxide may be, for example, but not limited to, an oxide of hafnium, aluminum, tantalum, zirconium, indium, or combinations thereof (e.g., hafnium oxide, aluminum oxide, tantalum oxide, zirconium oxide, indium oxide, hafnium zirconium oxide, hafnium aluminum oxide, hafnium tantalum oxide, or combinations thereof). In some embodiments, the at least one metal element doped in the metal oxide may be, for example, but not limited to, hafnium, aluminum, tantalum, zirconium, lanthanum, or combinations thereof. In some embodiments, the metal oxide doped with the at least one metal element may be, for example, but not limited to, hafnium oxide doped with tantalum, zirconium, tantalum, indium or combinations thereof, aluminum oxide doped with tantalum, zirconium, indium or combinations thereof, or a combination thereof. In some alternative embodiments, the lower high-k dielectric layer 16 may include a silicon-based dielectric material (for example, but not limited to, silicon oxide, silicon nitride, silicon oxynitride, or combinations thereof) optionally doped with at least one metal element (for example, but not limited to, zirconium, hafnium, lanthanum, tantalum, aluminum, or combinations thereof). A doping concentration of the at least one metal element doped in the metal oxide or the silicon-based dielectric material may be greater than about 50%. If the doping concentration is lower than about 50%, a forming voltage (V_{f}) of the semiconductor memory device 200A may not be efficiently reduced.

As shown in FIG. 7B, in some embodiments, the lower high-k dielectric layer 16 may include a first high-k dielectric sublayer 161 and a second high-k dielectric sublayer 162 disposed on the first high-k dielectric sublayer 161 opposite to the bottom electrode layer 15 (see FIG. 7A). The first high-k dielectric sublayer 161 may include the metal oxide or the metal oxide doped with the at least one metal element, which are described in the foregoing. In some embodiments, the first high-k dielectric sublayer 161 of the lower high-k dielectric layer 16 may have a thickness ranging from about 5 Å to about 100 Å. If the thickness of the first high-k dielectric sublayer 161 of the lower high-k dielectric layer 16 is less than about 5 Å, a reliability of the semiconductor memory device 200A may be adversely affected. If the thickness of the first high-k dielectric sublayer 161 of the lower high-k dielectric layer 16 is greater than about 100 Å, the forming voltage (V_{f}) of the semiconductor memory device 200A may be increased. The second high-k dielectric sublayer 162 of the lower high-k dielectric layer 16 may include the metal oxide, the metal oxide doped with the at least one metal element, or the silicon-based dielectric material optionally doped with the at least one metal element, which is described in the foregoing. The second high-k dielectric sublayer 162 of the lower high-k dielectric layer 16 may have a thickness ranging from about 0 Å to about 100 Å. If the thickness of the second high-k dielectric sublayer 162 of the lower high-k dielectric layer 16 is greater than about 100 Å, the forming voltage (V_{f}) of the semiconductor memory device 200A may be increased.

As shown in FIG. 7C, in some alternative embodiments, disposition of the first high-k dielectric sublayer 161 and the second high-k dielectric sublayer 162 of the lower high-k dielectric layer 16 may be different from that shown in FIG. 7B. In this case, the second high-k dielectric sublayer 162 of the lower high-k dielectric layer 16 is disposed between the bottom electrode layer 15 and the first high-k dielectric sublayer 161 of the lower high-k dielectric layer 16.

FIGS. 7D to 7F respectively illustrate various configurations of the lower high-k dielectric layer 16 which includes a set of the first high-k dielectric sublayers 161 and a set of the second high-k dielectric sublayers 162 disposed to alternate with the set of the first high-k dielectric sublayers 161 in the Z direction. It is noted that there are no particular limitations on a number of the first high-k dielectric sublayer 161 in the set of the first high-k dielectric sublayers 161, and a number of the second high-k dielectric sublayer 162 in the set of the second high-k dielectric sublayers 162.

As shown in FIG. 7D, the thickness of each of the first high-k dielectric sublayers 161 of the lower high-k dielectric layer 16 ranges from about 5 Å to about 100 Å, and the thickness of each of the second high-k dielectric sublayers 162 of the lower high-k dielectric layer 16 ranges from about 0.1 Å to about 10 Å. If the thickness of the second high-k dielectric sublayer 162 of the lower high-k dielectric layer 16 is less than about 0.1 Å, the reliability of the semiconductor memory device 200A may be adversely affected. If the thickness of the second high-k dielectric sublayer 162 of the lower high-k dielectric layer 16 is greater than about 10 Å, the forming voltage (V_{f}) of the semiconductor memory device 200A may be increased.

As shown in FIG. 7E, a topmost sublayer of the lower high-k dielectric layer 16 distal from the bottom electrode layer 15 (see FIG. 7A) is a topmost one of the second high-k dielectric sublayers 162 in the set of the second high-k dielectric sublayers 162. In this case, the thickness of the topmost one of the second high-k dielectric sublayers 162 in the set of the second high-k dielectric sublayers 162 may range from about 0 Å to about 100 Å, the thickness of each of the other sublayers of the second high-k dielectric sublayers 162 in the set of the second high-k dielectric sublayers 162 may range from about 0.1 Å to about 10 Å, and the thickness of each of the first high-k dielectric sublayers 161 in the set of the first high-k dielectric sublayers 161 may range from about 5 Å to about 100 Å. If the thickness of the topmost one of the second high-k dielectric sublayers 162 in the set of the second high-k dielectric sublayers 162 is greater than about 100 Å, the forming voltage (V_{f}) of the semiconductor memory device 200A may be increased.

As shown in FIG. 7F, a bottommost sublayer of the lower high-k dielectric layer 16 proximate to the bottom electrode layer 15 (see FIG. 7A) is a bottommost one of the second high-k dielectric sublayers 162 in the set of the second high-k dielectric sublayers 162. In this case, the thickness of the bottommost one of the second high-k dielectric sublayers 162 in the set of the second high-k dielectric sublayers 162 may range from about 0 Å to about 100 Å, the thickness of each of the other sublayers of the second high-k dielectric sublayers 162 in the set of the second high-k dielectric sublayers 162 may range from about 0.1 Å to about 10 Å, and the thickness of each of the first high-k dielectric sublayers 161 in the set of the first high-k dielectric sublayers 161 may range from about 5 Å to about 100 Å. If the thickness of the bottommost one of the second high-k dielectric sublayers 162 in the set of the second high-k dielectric sublayers 162 is greater than about 100 Å, the forming voltage (V_{f}) of the semiconductor memory device 200A may be increased.

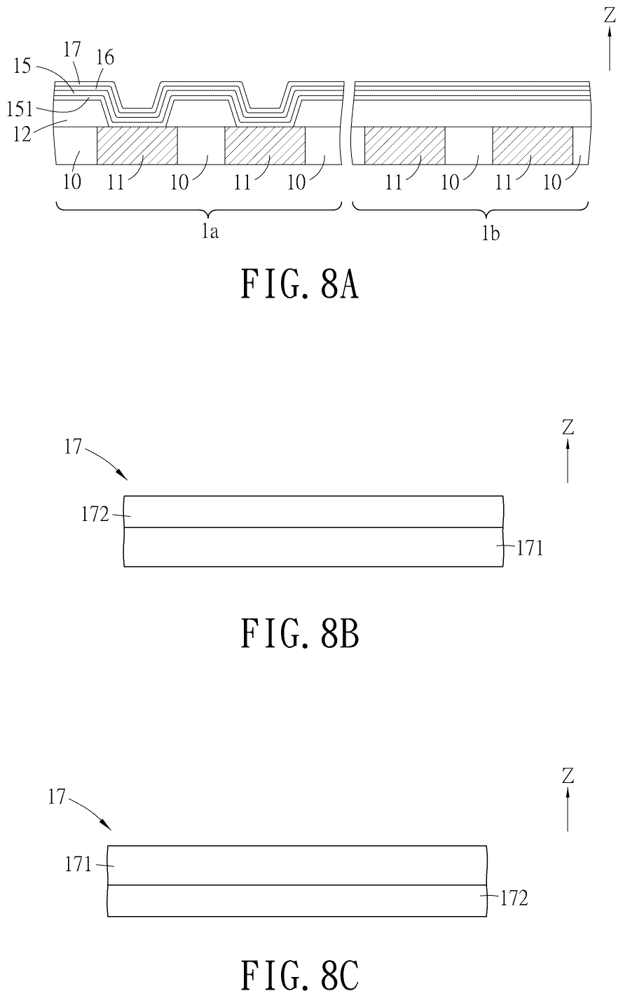

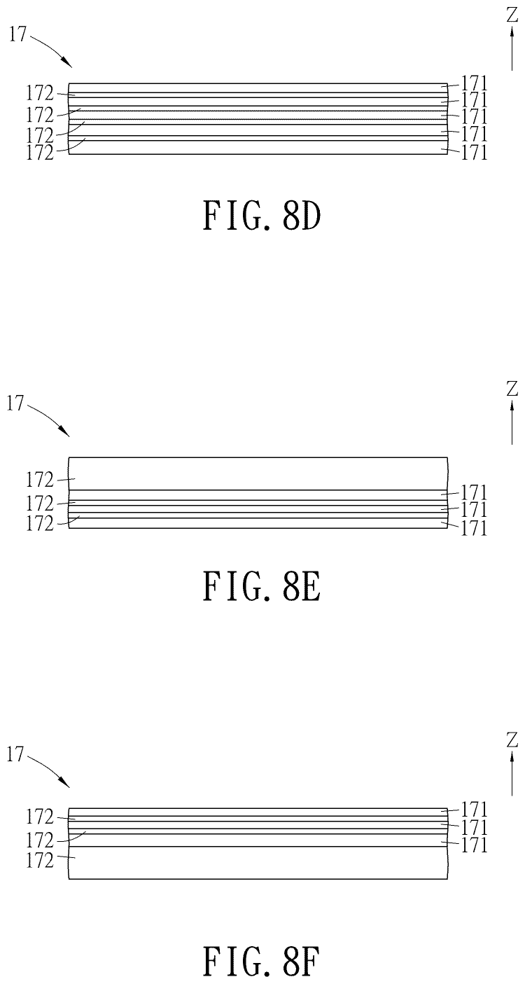

Referring to FIG. 1A and the example illustrated in FIGS. 8A to 8F, the method 100A then proceeds to step S07, where an upper high-k dielectric layer 17 is conformally formed on the structure shown in FIG. 7A. FIGS. 8B to 8F are schematic enlarged views respectively illustrating various configurations of the upper high-k dielectric layer 17 shown in FIG. 8A. The material and process for forming the upper high-k dielectric layer 17 are similar to those for forming the lower high-k dielectric layer 16, except that the at least one metal element doped in the metal oxide or the silicon-based dielectric material for forming the upper high-k dielectric layer 17 is different from the at least one metal element doped in the metal oxide or the silicon-based dielectric material for forming the lower high-k dielectric layer 16, and/or that the metal oxide or the silicon-based dielectric material for forming the upper high-k dielectric layer 17 is different from the metal oxide or the silicon-based dielectric material for forming the lower high-k dielectric layer 16. For example, the lower high-k dielectric layer 16 is made of hafnium oxide doped with tantalum, while the upper high-k dielectric layer 17 is made of hafnium oxide doped with zirconium.

As shown in FIG. 8B, in some embodiments, the upper high-k dielectric layer 17 may include a first high-k dielectric sublayer 171 and a second high-k dielectric sublayer 172 disposed on the first high-k sublayer 171 opposite to the lower high-k dielectric layer 16. The first high-k dielectric sublayer 171 of the upper high-k dielectric layer 17 may include the metal oxide or the metal oxide doped with the at least one metal element, which are described in step S06. The first high-k dielectric sublayer 171 of the upper high-k dielectric layer 17 may have a thickness ranging from about 5 Å to about 100 Å. If the thickness of the first high-k dielectric sublayer 171 of the upper high-k dielectric layer 17 is less than about 5 Å, the reliability of the semiconductor memory device 200A may be adversely affected. If the thickness of the first high-k dielectric sublayer 171 of the upper high-k dielectric layer 17 is greater than about 100 Å, the forming voltage (V_{f}) of the semiconductor memory device 200A may be increased. In some embodiments, the metal oxide for forming the first high-k dielectric sublayer 171 of the upper high-k dielectric layer 17 is different from the metal oxide for forming the first high-k dielectric sublayer 161 of the lower high-k dielectric layer 16. In some embodiments, the metal oxide for forming the first high-k dielectric sublayer 171 of the upper high-k dielectric layer 17 is the same as the metal oxide for forming the first high-k dielectric sublayer 161 of the lower high-k dielectric layer 16, while the at least one metal element doped in the metal oxide for forming the first high-k dielectric sublayer 171 of the upper high-k dielectric layer 17 is different from the at least one metal element doped in the metal oxide for forming the first high-k dielectric sublayer 161 of the lower high-k dielectric layer 16. The second high-k dielectric sublayer 172 of the upper high-k dielectric layer 17 may include the metal oxide optionally doped with the at least one metal element, or the silicon-based dielectric material optionally doped with the at least one metal element. The second high-k dielectric sublayer 172 of the upper high-k dielectric layer 17 may have a thickness ranging from about 0 Å to about 100 Å. If the thickness of the second high-k dielectric sublayer 172 of the upper high-k dielectric layer 17 is greater than about 100 Å, the forming voltage (V_{f}) of the semiconductor memory device 200A may be increased. In some embodiments, the metal oxide or the silicon-based dielectric material for forming the second high-k dielectric sublayer 172 of the upper high-k dielectric layer 17 is different from the metal oxide or the silicon-based dielectric material for forming the second high-k dielectric sublayer 162 of the lower high-k dielectric layer 16. In some embodiments, the metal oxide for forming the second high-k dielectric sublayer 172 of the upper high-k dielectric layer 17 is the same as the metal oxide for forming the second high-k dielectric sublayer 162 of the lower high-k dielectric layer 16, while the at least one metal element doped in the metal oxide for forming the second high-k dielectric sublayer 172 of the upper high-k dielectric layer 17 is different from the at least one metal element doped in the metal oxide for forming the second high-k dielectric sublayer 162 of the lower high-k dielectric layer 16.

As shown in FIG. 8C, in some alternative embodiments, disposition of the first high-k dielectric sublayer 171 and the second high-k dielectric sublayer 172 of the upper high-k dielectric layer 17 may be different from that shown in FIG. 8B. In this case, the second high-k dielectric sublayer 172 of the upper high-k dielectric layer 17 is disposed between the lower high-k dielectric layer 16 and the first high-k dielectric sublayer 171 of the upper high-k dielectric layer 17.

FIGS. 8D to 8F respectively illustrate various configurations of the upper high-k dielectric layer 17 which includes a set of the first high-k dielectric sublayers 171 and a set of the second high-k dielectric sublayers 172 disposed to alternate with the set of the first high-k dielectric sublayers 171 in the Z direction. It is noted that there are no particular limitations on a number of the first high-k dielectric sublayer 171 in the set of the first high-k dielectric sublayers 171, and a number of the second high-k dielectric sublayer 172 in the set of the second high-k dielectric sublayers 172.

As shown in FIG. 8D, the thickness of each of the first high-k dielectric sublayers 171 of the upper high-k dielectric layer 17 ranges from about 5 Å to about 100 Å, and the thickness of each of the second high-k dielectric sublayers 172 of the upper high-k dielectric layer 17 ranges from about 0.1 Å to about 10 Å. If the thickness of the second high-k dielectric sublayer 172 of the upper high-k dielectric layer 17 is less than about 0.1 Å, the reliability of the semiconductor memory device 200A may be adversely affected. If the thickness of the second high-k dielectric sublayer 172 of the upper high-k dielectric layer 17 is greater than about 10 Å, the forming voltage (V_{f}) of the semiconductor memory device 200A may be increased.

As shown in FIG. 8E, a topmost sublayer of the upper high-k dielectric layer 17 distal from the lower high-k dielectric layer 16 (see FIG. 8A) is a topmost one of the second high-k dielectric sublayers 172 in the set of the second high-k dielectric sublayers 172. In this case, the thickness of the topmost one of the second high-k dielectric sublayers 172 in the set of the second high-k dielectric sublayers 172 may range from about 0 Å to about 100 Å, the thickness of each of the other sublayers of the second high-k dielectric sublayers 172 in the set of the second high-k dielectric sublayers 172 may range from about 0.1 Å to about 10 Å, and the thickness of each of the first high-k dielectric sublayers 171 in the set of the first high-k dielectric sublayers 171 may range from about 5 Å to about 100 Å. If the thickness of the topmost one of the second high-k dielectric sublayers 172 in the set of the second high-k dielectric sublayers 172 is greater than about 100 Å, the forming voltage (V_{f}) of the semiconductor memory device 200A may be increased.

As shown in FIG. 8F, a bottommost sublayer of the upper high-k dielectric layer 17 is a bottommost one of the second high-k dielectric sublayers 172 in the set of the second high-k dielectric sublayers 172. In this case, the thickness of the bottommost one of the second high-k dielectric sublayers 172 in the set of the second high-k dielectric sublayers 172 may range from about 0 Å to about 100 Å, the thickness of each of the other sublayers of the second high-k dielectric sublayers 172 in the set of the second high-k dielectric sublayers 172 may range from about 0.1 Å to about 10 Å, and the thickness of each of the first high-k dielectric sublayers 171 in the set of the first high-k dielectric sublayers 171 may range from about 5 Å to about 100 Å. If the thickness of the bottommost one of the second high-k dielectric sublayers 172 in the set of the second high-k dielectric sublayers 172 is greater than about 100 Å, the forming voltage (V_{f}) of the semiconductor memory device 200A may be increased.

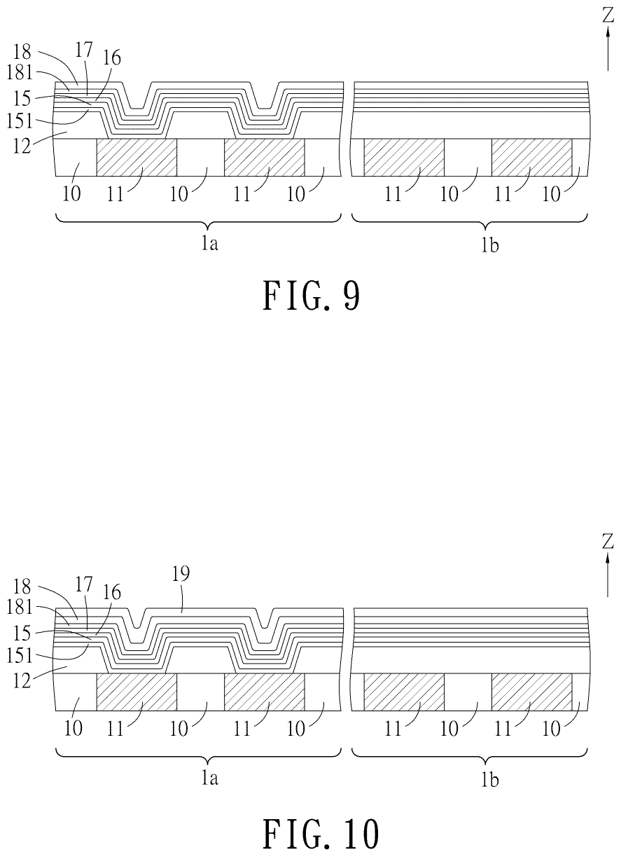

Referring to FIG. 1A and the example illustrated in FIG. 9, the method 100A then proceeds to step S08, where a top electrode layer 18 is conformally formed on the structure shown in FIG. 8A. Step S08 may be performed by a suitable deposition process, for example, but not limited to, CVD, MOCVD, PVD, ALD, or other suitable deposition processes. In some embodiments, the top electrode layer 18 may be formed as a single layer structure or a multi-layered structure.

In a case that the top electrode layer 18 is formed as a single layer structure, the top electrode layer 18 may include, for example, but not limited to, the inert metal, the alloy of the inert metal, or the active metallic material as described above in step S05 and thus details thereof are omitted for the sake of brevity. In some embodiments, the top electrode layer 18 is made of the inert metal, the alloy of the inert metal, or the active metallic material. When the top electrode layer 18 includes the inert metal or the alloy of the inert metal, the top electrode layer 18 may have a thickness ranging from about 20 Å to about 350 Å. If the thickness of the top electrode layer 18 is less than about 20 Å, metal atoms of other layers (e.g., the upper high-k dielectric layer 17) may diffuse into the top electrode layer 18, which may adversely affect the properties of the top electrode layer 18. If the thickness of the top electrode layer 18 is greater than about 350 Å, the total thickness of the semiconductor memory device 200A may be increased, which is not conducive to scaling down of the size of the semiconductor memory device 200A.

In a case that the top electrode layer 18 is formed as a multi-layered structure, the top electrode layer 18 may include an inert metal sublayer (not shown) and an active metal sublayer (not shown), which are respectively the same as or similar to the inert metal sublayer and the active metal sublayer of the multi-layered structure of the bottom electrode layer 15 as described in the foregoing, and thus details thereof are omitted for the sake of brevity. In some embodiments, the inert metal sublayer of the top electrode layer 18 may have a thickness ranging from about 20 Å to about 350 Å. In some embodiments, the active metal sublayer of the top electrode layer 18 may have a thickness ranging from about 0 Å to about 30 Å. If the thickness of the active metal sublayer of the top electrode layer 18 is greater than about 30 Å, an amount of metal atoms in the active metal sublayer of the top electrode layer 18 may be excessive, which may adversely affect the device performance of the semiconductor memory device 200A. In some embodiments, the active metal sublayer of the top electrode layer 18 is proximate to the upper high-k dielectric layer 17 relative to the inert metal sublayer of the top electrode layer 18.

As shown in FIG. 9, in some embodiments, before formation of the top electrode layer 18, a top barrier layer 181 is conformally formed on the structure shown in FIG. 8A. The top barrier layer 181 is disposed on the upper high-k dielectric layer 17 opposite to the lower high-k dielectric layer 16. The material and process for forming the top barrier layer 181 may be the same as or similar to those for forming the bottom barrier layer 151, and thus details thereof are omitted for the sake of brevity. In some embodiments, the top barrier layer 181 and the top electrode layer 18 are made of different materials. In some embodiments, the top barrier layer 181 may be a sublayer (e.g., a bottommost sublayer) of the top electrode layer 18 when the top electrode layer 18 is formed as a multi-layered structure.

In some embodiments, a chemical activity of the top electrode layer 18 with respect to an oxidation capability of metal element(s) included in the top electrode layer 18 is different from a chemical activity of the bottom electrode layer 15 with respect to an oxidation capability of metal element(s) included in the bottom electrode layer 15. In some embodiments, one of the bottom electrode layer 15 and the top electrode layer 18 is formed as the single layer structure made of the inert metal or the alloy of the inert metal, or as the multi-layered structure including the inert metal sublayer and the active metal sublayer (which are described in the foregoing), and the other one of the bottom electrode layer 15 and the top electrode layer 18 is formed as the single layer structure made of the active metallic material. For example, when the bottom electrode layer 15 is formed as the single layer structure made of the inert metal or the alloy of the inert metal, or as the multi-layered structure including the inert metal sublayer and the active metal sublayer, the top electrode layer 18 is formed as the single layer structure made of the active metallic material. In this case, the chemical activity of the bottom electrode layer 15 is lower than that of the top electrode layer 18. In some embodiments, when the chemical activity of the bottom electrode layer 15 is lower than that of the top electrode layer 18, oxygen atoms of the upper high-k dielectric layer 17 may tend to migrate into the top electrode layer 18 relative to oxygen atoms of the lower high-k dielectric layer 16. In some embodiments, when the chemical activity of the bottom electrode layer 15 is greater than that of the top electrode layer 18, the oxygen atoms of the lower high-k dielectric layer 16 may tend to migrate into the bottom electrode layer 15 relative to the oxygen atoms of the upper high-k dielectric layer 17.

Referring to FIG. 1A and the example illustrated in FIG. 10, the method 100A then proceeds to step S09, where a mask layer 19 is formed on the structure shown in FIG. 9. The mask layer 19 may be formed by a suitable deposition process, for example, but not limited to, CVD, PVD, ALD, or other suitable deposition processes. The mask layer 19 is formed on the top electrode layer 18 opposite to the upper high-k dielectric layer 17. The mask layer 19 may include, for example, but not limited to, titanium nitride, silicon oxide, silicon nitride, silicon carbide nitride, silicon oxide nitride, metal oxide (e.g., titanium oxide, aluminum oxide or the like), or combinations thereof. Other suitable materials for the mask layer 19 are within the contemplated scope of the present disclosure.

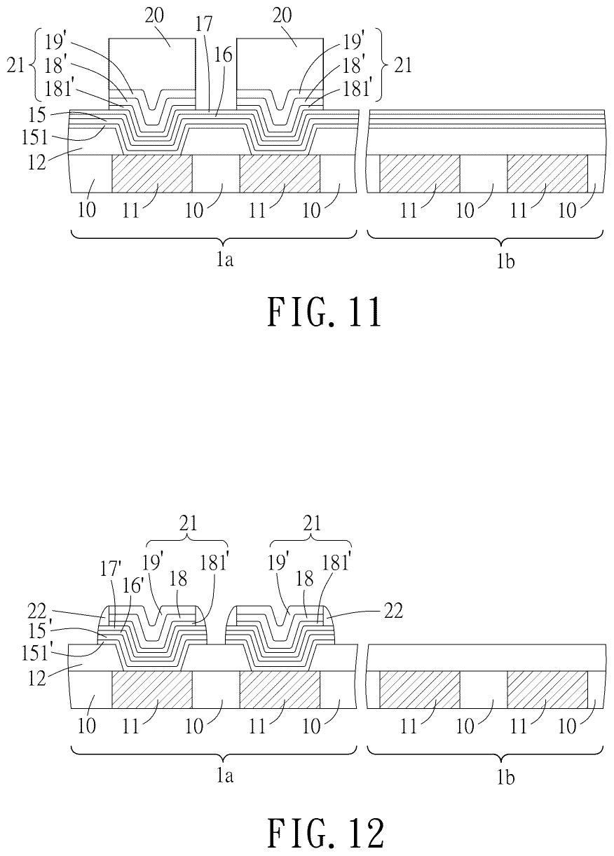

Referring to FIG. 1A and the example illustrated in FIG. 11, the method 100A then proceeds to step S10, where the mask layer 19, the top electrode layer 18, and the top barrier layer 181 shown in FIG. 10 are patterned to form a plurality of masks 19′, a plurality of top electrodes 18′, and a plurality of top barrier portions 181′ in the device memory region 1a. Step S10 may be performed by photolithography (including an etching process) as described above in step S02, and thus details thereof are omitted for the sake of brevity. In this step, a patterned photoresist layer 20 is formed on the mask layer 19, and is used as a mask for etching the mask layer 19, the top electrode layer 18, and the top barrier layer 181 in the etching process. Each of the top electrodes 18′, a corresponding one of the top barrier portions 181′ and a corresponding one of the masks 19′ may be collectively referred to as a stack 21 (i.e., a plurality of the stacks 21 are formed in this step). After this step, the patterned photoresist layer 20 is removed by, for example, but not limited to, an ashing process or other suitable removal processes.

Referring to FIG. 1B and the example illustrated in FIG. 12, the method 100A then proceeds to step S11, where a plurality of pairs of spacers 22, a plurality of upper high-k dielectric portions 17′, a plurality of lower high-k dielectric portions 16′, a plurality of bottom electrodes 15′, and a plurality of bottom barrier portions 151′ are formed. Each pair of the spacers 22 respectively cover two lateral sides of a corresponding one of the stacks 21. Step S11 may include sub-steps (i) to (iii).

In sub-step (i), a spacer layer (not shown) for forming the spacers 22 is conformally formed on the stacks 21 and the upper high-k dielectric layer 17. The spacer layer may be formed by a suitable deposition process, for example, but not limited to, CVD, PVD, ALD, or other suitable deposition processes. The spacer layer may include, for example, but not limited to, silicon nitride, silicon oxide, silicon carbide, silicon oxynitride, silicon oxycarbide, silicon oxycarbon nitride, or combinations thereof. Other suitable materials for forming the spacers 22 are within the contemplated scope of the present disclosure.

In sub-step (ii), the spacer layer is partially removed by photolithography (including an etching process). In this sub-step, a patterned photoresist layer (not shown) is formed on the spacer layer and is used as a mask for etching the spacer layer in the etching process or in a subsequent etching process in sub-step (iii). The etching process may be an anisotropically etching process (e.g., an anisotropically dry etching process or other suitable etching processes). After this sub-step, the spacer layer is formed into the spacers 22.

In sub-step (iii), portions of the upper high-k dielectric layer 17, portions of the lower high-k dielectric layer 16, portions of the bottom electrode layer 15, and portions of the bottom barrier layer 151 that are exposed from the stacks 21 and the spacers 22 are etched by a suitable etching process, for example, but not limited to, dry etching, wet etching, a combination thereof, or other suitable etching processes. After this sub-step, the upper high-k dielectric layer 17 is formed into the upper high-k dielectric portions 17′ in the device memory region la, the lower high-k dielectric layer 16 is formed into the lower high-k dielectric portions 16′ in the device memory region 1a, the bottom electrode layer 15 is formed into the bottom electrodes 15′ in the device memory region la, and the bottom barrier layer 151 is formed into the bottom barrier portions 151′ in the device memory region 1a. In some embodiments, each of the lower high-k dielectric portions 16′ includes at least one first high-k dielectric subportion (formed from the first high-k dielectric sublayer 161 shown in FIGS. 7B to 7F) and at least one second high-k dielectric subportion (formed from the second high-k dielectric sublayer 162 shown in FIGS. 7B to 7F), and each of the upper high-k dielectric portions 17′ includes at least one first high-k dielectric subportion (formed from the first high-k dielectric sublayer 171 shown in FIGS. 8B to 8F) and at least one second high-k dielectric subportion (formed from the second high-k dielectric sublayer 172 shown in FIGS. 8B to 8F). After this sub-step, the patterned photoresist layer is removed by, for example, but not limited to, an ashing process or other suitable removal processes.

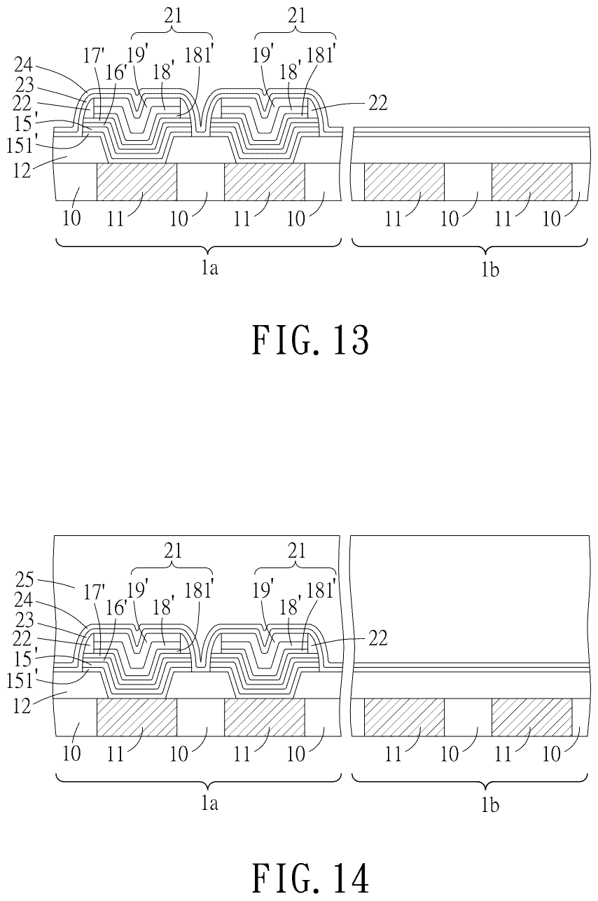

Referring to FIG. 1B and the example illustrated in FIG. 13, the method 100A then proceeds to step S12, where a second etch stop layer 23 and a buffer layer 24 are sequentially formed on the structure shown in FIG. 12. Step S12 may include sub-steps (i) and (ii).

In sub-step (i), the second etch stop layer 23 is conformally formed on the structure shown in FIG. 12. The material and process for forming the second etch stop layer 23 may be the same as or similar to those for forming the first etch stop layer 12, and thus details thereof are omitted for the sake of brevity.

In sub-step (ii), the buffer layer 24 is formed on the second etch stop layer 23. In this sub-step, the buffer layer 24 may be formed by a suitable deposition process, for example, but not limited to, CVD, PECVD, or other suitable deposition processes. In some embodiments, the buffer layer 24 may include, for example, but not limited to, tetraethyl orthosilicae (TEOS). Other suitable materials for the buffer layer 24 are within the contemplated scope of the present disclosure.

Referring to FIG. 1B and the example illustrated in FIG. 14, the method 100A then proceeds to step S13, where a second dielectric layer 25 is formed over the structure shown in FIG. 13. The material and process for forming the second dielectric layer 25 may be similar to or the same as those for forming the first dielectric layer 10, and thus details thereof are omitted for the sake of brevity. After this step, a planarization process (e.g., CMP or other suitable planarization processes) may be performed to remove an excess portion of the second dielectric layer 25.

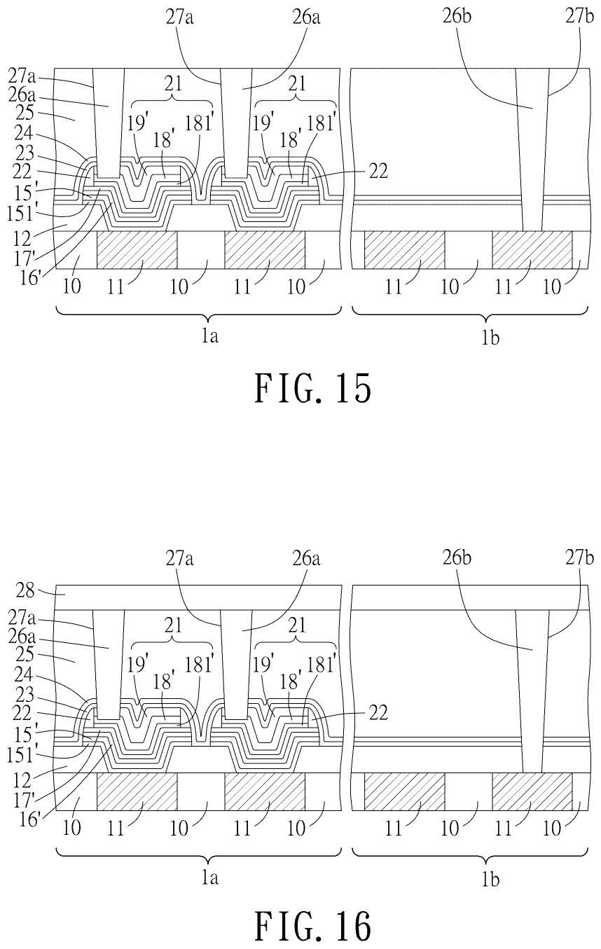

Referring to FIG. 1B and the example illustrated in FIG. 15, the method 100A then proceeds to step S14, where a plurality of contact vias 26a, 26b are formed in the second dielectric layer 25. Step S14 may include sub-steps (i) to (iii).

In sub-step (i), the second dielectric layer 25 is patterned by photolithography, so as to form a plurality of second openings 27a, 27b. Each of the second openings 27a penetrates the second dielectric layer 25, the buffer layer 24, the second etch stop layer 23 and a corresponding one of the masks 19′, and extends into a corresponding one of the top electrodes 18′ in the device memory region 1a. In some embodiments, each of the second openings 27a may penetrate the second dielectric layer 25, the buffer layer 24, the second etch stop layer 23 and the corresponding one of the masks 19′, and may terminate at an upper surface of the corresponding one of the top electrodes 18′ in the device memory region 1a. The second opening 27b penetrates the second dielectric layer 25, the buffer layer 24, the second etch stop layer 23 and the first etch stop layer 12 to expose a corresponding one of the first metal lines 11 in the device peripheral region 1b.

In sub-step (ii), a contact material for forming the contact vias 26a, 26b is deposited on the second dielectric layer 25 to fill the second openings 27a, 27b. The deposition of the contact material may be performed by a suitable deposition process, for example, but not limited to, CVD, PVD, electroless plating, electroplating, or other suitable deposition processes. The contact material may include, for example, but not limited to, copper, aluminum, tungsten, or combinations thereof. Other suitable materials for the contact vias 26a, 26b are within the contemplated scope of the present disclosure.

In sub-step (iii), an excess portion of the contact material on the second dielectric layer 25 is removed, so as to form the contact vias 26a, 26b. Removal of the excess portion of the contact material may be performed by a suitable planarization process, for example, but not limited to, CMP or other suitable planarization processes. The contact vias 26a filling the second openings 27a are electrically and respectively connected to the top electrodes 18′ in the device memory region la. The contact via 26b filling the second opening 27b is electrically and directly connected to a corresponding one of the first metal lines 11 in the device peripheral region 1b.

Referring to FIG. 1B and the example illustrated in FIG. 16, the method 100A then proceeds to step S15, where a third dielectric layer 28 is formed on the second dielectric layer 25 and the contact vias 26a, 26b. The material and process for forming the third dielectric layer 28 may be similar to or the same as those for forming the first dielectric layer 10 as described above in step S01, and thus details thereof are omitted for the sake of brevity.

Referring to FIG. 1B and the example illustrated in FIG. 17, the method 100A then proceeds to step S16, where a plurality of second metal lines 29 are formed in the third dielectric layer 28 such that the second metal lines 29 are respectively connected to the contact vias 26a, 26b. The material and process for forming the second metal lines 29 may be similar to or the same as those for forming the first metal lines 11 as described above in step S02, and thus details thereof are omitted for the sake of brevity. After this step, the semiconductor memory device 200A is obtained, and includes a plurality of memory structures in the device memory region la. Each of the memory structures includes one of the top electrodes 18′, a corresponding one of the upper high-k dielectric portions 17′, a corresponding one of the lower high-k dielectric portions 16′, and a corresponding one of the bottom electrodes 15′.

In a semiconductor memory device of this disclosure, a bottom electrode and a top electrode are made of different novel electrode materials (e.g., an inert metal, an alloy of the inert metal, an active metallic material, or combinations thereof), and a lower high-k dielectric portion and/or an upper high-k dielectric portion, which are stacked between the bottom electrode and the top electrode, are made of a dielectric material (e.g., an oxide-based material or a nitride-based material) optionally doped with different metal atoms. Therefore, a forming voltage (V_{f}) of the semiconductor memory device can be reduced efficiently and device performance of the semiconductor memory device can be further improved.

In accordance with some embodiments of the present disclosure, a semiconductor memory device includes a dielectric layer, a metal line, a bottom electrode, a high-k dielectric portion, and a top electrode. The metal line is disposed in the dielectric layer. The bottom electrode is disposed on and electrically connected to the metal line. The high-k dielectric portion is disposed on the bottom electrode opposite to the dielectric layer. The top electrode is disposed on the high-k dielectric portion opposite to the bottom electrode. A chemical activity of the top electrode with respect to an oxidation capability of a metal element included in the top electrode is different from a chemical activity of the bottom electrode with respect to an oxidation capability of a metal element included in the bottom electrode.

In accordance with some embodiments of the present disclosure, one of the bottom electrode and the top electrode includes an inert metal, an alloy of the inert metal, a combination of the inert metal and an active metallic material, or a combination of the alloy of the inert metal and the active metallic material, and the other one of the bottom electrode and the top electrode includes the active metallic material.

In accordance with some embodiments of the present disclosure, the inert metal is palladium, platinum, darmstadtium, ruthenium, molybdenum, or iridium.

In accordance with some embodiments of the present disclosure, the active metallic material includes tantalum nitride, titanium nitride, tantalum, titanium, tungsten, aluminum, nickel, hafnium, lanthanum, zirconium, or combinations thereof.

In accordance with some embodiments of the present disclosure, the one of the bottom electrode and the top electrode is configured as a multi-layered structure including an inert metal sublayer made of the inert metal or the alloy of the inert metal, and an active metal sublayer made of the active metallic material and disposed between the inert metal sublayer and the high-k dielectric portion.

In accordance with some embodiments of the present disclosure, the high-k dielectric portion includes a metal oxide, or a metal oxide doped with at least one metal element different from a metal element of the metal oxide, or a silicon-based dielectric material, or a silicon-based dielectric material doped with at least one metal element, or combinations thereof.

In accordance with some embodiments of the present disclosure, the metal oxide is an oxide of hafnium, aluminum, tantalum, zirconium, indium, or combinations thereof.

In accordance with some embodiments of the present disclosure, the at least one metal element doped in the metal oxide or the silicon-based dielectric material is hafnium, aluminum, tantalum, zirconium, lanthanum, or combinations thereof.

In accordance with some embodiments of the present disclosure, the silicon-based dielectric material includes silicon oxide, silicon nitride, silicon oxynitride, or combinations thereof.

In accordance with some embodiments of the present disclosure, a semiconductor memory device includes a dielectric layer, a metal line, a bottom electrode, a lower high-k dielectric portion, a top electrode, and a pair of spacers. The metal line is disposed in the dielectric layer. The bottom electrode is disposed on and electrically connected to the metal line. The lower high-k dielectric portion is disposed on the bottom electrode opposite to the dielectric layer. The top electrode is disposed on the lower high-k dielectric portion opposite to the bottom electrode. The spacers are disposed on the lower high-k dielectric portion opposite to the bottom electrode and laterally cover the top electrode. One of the bottom electrode and the top electrode includes an inert metal, an alloy of the inert metal, a combination of the inert metal and an active metallic material, or a combination of the alloy of the inert metal and the active metallic material, and the other one of the bottom electrode and the top electrode includes the active metallic material, such that a chemical activity of the top electrode with respect to an oxidation capability of a metal element included in the top electrode is different from a chemical activity of the bottom electrode with respect to an oxidation capability of a metal element included in the bottom electrode.

In accordance with some embodiments of the present disclosure, the semiconductor memory device further includes an upper high-k dielectric portion disposed between the lower high-k dielectric portion and the top electrode, wherein the lower high-k dielectric portion and the upper high-k dielectric portion include different materials.

In accordance with some embodiments of the present disclosure, each of the lower high-k dielectric portion and the upper high-k dielectric portion includes a first high-k dielectric subportion and a second high-k dielectric subportion which include different materials, the first high-k dielectric subportion includes a first metal oxide or a first metal oxide doped with at least one first metal element, and the second high-k dielectric subportion includes a second metal oxide, or a second metal oxide doped with at least one second metal element, or a silicon-based dielectric material, or a silicon-based dielectric material doped with the at least one second metal element.

In accordance with some embodiments of the present disclosure, the first high-k dielectric subportion is made of the first metal oxide, the second high-k dielectric subportion is made of the second metal oxide, and the first metal oxide is different from the second metal oxide.

In accordance with some embodiments of the present disclosure, the first high-k dielectric subportion is made of the first metal oxide doped with the at least one first metal element, the second high-k dielectric subportion is made of the second metal oxide doped with the at least one second metal element, and the at least one first metal element is different from the at least one second metal element.

In accordance with some embodiments of the present disclosure, the first high-k dielectric subportion of each of the lower high-k dielectric portion and the upper high-k dielectric portion is made of the first metal oxide, and the first metal oxide of the first high-k dielectric subportion of the lower high-k dielectric portion is different from the first metal oxide of the first high-k dielectric subportion of the upper high-k dielectric portion.

In accordance with some embodiments of the present disclosure, the second high-k dielectric subportion of each of the lower high-k dielectric portion and the upper high-k dielectric portion is made of the second metal oxide, and the second metal oxide of the second high-k dielectric subportion of the lower high-k dielectric portion is different from the second metal oxide of the second high-k dielectric subportion of the upper high-k dielectric portion.

In accordance with some embodiments of the present disclosure, a method for manufacturing a semiconductor memory device includes: forming an interconnect structure on a semiconductor substrate, the interconnect structure including a dielectric layer and a metal line disposed in the dielectric layer; forming a bottom electrode layer on the interconnect structure opposite to the semiconductor substrate; forming a lower high-k dielectric layer on the bottom electrode layer opposite to the interconnect structure; and forming a top electrode layer on the lower high-k dielectric layer opposite to the bottom electrode layer. A chemical activity of the top electrode layer with respect to an oxidation capability of a metal element included in the top electrode layer is different from a chemical activity of the bottom electrode layer with respect to an oxidation capability of a metal element included in the bottom electrode layer.

In accordance with some embodiments of the present disclosure, one of the bottom electrode layer and the top electrode layer includes an inert metal, an alloy of the inert metal, a combination of the inert metal and an active metallic material, or a combination of the alloy of the inert metal and the active metallic material, and the other one of the bottom electrode layer and the top electrode layer includes the active metallic material.

In accordance with some embodiments of the present disclosure, the inert metal is palladium, platinum, darmstadtium, ruthenium, molybdenum, or iridium.

In accordance with some embodiments of the present disclosure, the active metallic material includes tantalum nitride, titanium nitride, tantalum, titanium, tungsten, aluminum, nickel, hafnium, lanthanum, zirconium, or combinations thereof.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor memory device, comprising:
a dielectric layer;
a metal line disposed in the dielectric layer;
a bottom electrode disposed on and electrically connected to the metal line;
a high-k dielectric portion disposed on the bottom electrode opposite to the dielectric layer; and
a top electrode disposed on the high-k dielectric portion opposite to the bottom electrode,
a chemical activity of the top electrode with respect to an oxidation capability of a metal element included in the top electrode being different from a chemical activity of the bottom electrode with respect to an oxidation capability of a metal element included in the bottom electrode.

2. The semiconductor memory device as claimed in claim 1, wherein one of the bottom electrode and the top electrode includes an inert metal, an alloy of the inert metal, a combination of the inert metal and an active metallic material, or a combination of the alloy of the inert metal and the active metallic material, and the other one of the bottom electrode and the top electrode includes the active metallic material.

3. The semiconductor memory device as claimed in claim 2, wherein the inert metal is palladium, platinum, darmstadtium, ruthenium, molybdenum, or iridium.

4. The semiconductor memory device as claimed in claim 2, wherein the active metallic material includes tantalum nitride, titanium nitride, tantalum, titanium, tungsten, aluminum, nickel, hafnium, lanthanum, zirconium, or combinations thereof.

5. The semiconductor memory device as claimed in claim 2, wherein the one of the bottom electrode and the top electrode is configured as a multi-layered structure including:
an inert metal sublayer made of the inert metal or the alloy of the inert metal, and
an active metal sublayer made of the active metallic material and disposed between the inert metal sublayer and the high-k dielectric portion.

6. The semiconductor memory device as claimed in claim 1, wherein the high-k dielectric portion includes a metal oxide, or a metal oxide doped with at least one metal element different from a metal element of the metal oxide, or a silicon-based dielectric material, or a silicon-based dielectric material doped with at least one metal element, or combinations thereof.

7. The semiconductor memory device as claimed in claim 6, wherein the metal oxide is an oxide of hafnium, aluminum, tantalum, zirconium, indium, or combinations thereof.

8. The semiconductor memory device as claimed in claim 6, wherein the at least one metal element doped in the metal oxide or the silicon-based dielectric material is hafnium, aluminum, tantalum, zirconium, lanthanum, or combinations thereof.

9. The semiconductor memory device as claimed in claim 6, wherein the silicon-based dielectric material includes silicon oxide, silicon nitride, silicon oxynitride, or combinations thereof.

10. A semiconductor memory device, comprising:
a dielectric layer;
a metal line disposed in the dielectric layer;
a bottom electrode disposed on and electrically connected to the metal line;
a lower high-k dielectric portion disposed on the bottom electrode opposite to the dielectric layer;
a top electrode disposed on the lower high-k dielectric portion opposite to the bottom electrode; and
a pair of spacers disposed on the lower high-k dielectric portion opposite to the bottom electrode and laterally covering the top electrode,
one of the bottom electrode and the top electrode including an inert metal, an alloy of the inert metal, a combination of the inert metal and an active metallic material, or a combination of the alloy of the inert metal and the active metallic material, and the other one of the bottom electrode and the top electrode including the active metallic material, such that a chemical activity of the top electrode with respect to an oxidation capability of a metal element included in the top electrode is different from a chemical activity of the bottom electrode with respect to an oxidation capability of a metal element included in the bottom electrode.

11. The semiconductor memory device as claimed in claim 10, further comprising an upper high-k dielectric portion disposed between the lower high-k dielectric portion and the top electrode, wherein the lower high-k dielectric portion and the upper high-k dielectric portion include different materials.

12. The semiconductor memory device as claimed in claim 11, wherein each of the lower high-k dielectric portion and the upper high-k dielectric portion includes a first high-k dielectric subportion and a second high-k dielectric subportion which include different materials,
the first high-k dielectric subportion includes a first metal oxide or a first metal oxide doped with at least one first metal element, and
the second high-k dielectric subportion includes a second metal oxide, or a second metal oxide doped with at least one second metal element, or a silicon-based dielectric material, or a silicon-based dielectric material doped with the at least one second metal element.

13. The semiconductor memory device as claimed in claim 12, wherein
the first high-k dielectric subportion is made of the first metal oxide,
the second high-k dielectric subportion is made of the second metal oxide, and
the first metal oxide is different from the second metal oxide.

14. The semiconductor memory device as claimed in claim 12, wherein
the first high-k dielectric subportion is made of the first metal oxide doped with the at least one first metal element,
the second high-k dielectric subportion is made of the second metal oxide doped with the at least one second metal element, and
the at least one first metal element is different from the at least one second metal element.

15. The semiconductor memory device as claimed in claim 12, wherein
the first high-k dielectric subportion of each of the lower high-k dielectric portion and the upper high-k dielectric portion is made of the first metal oxide, and
the first metal oxide of the first high-k dielectric subportion of the lower high-k dielectric portion is different from the first metal oxide of the first high-k dielectric subportion of the upper high-k dielectric portion.

16. The semiconductor memory device as claimed in claim 12, wherein
the second high-k dielectric subportion of each of the lower high-k dielectric portion and the upper high-k dielectric portion is made of the second metal oxide, and
the second metal oxide of the second high-k dielectric subportion of the lower high-k dielectric portion is different from the second metal oxide of the second high-k dielectric subportion of the upper high-k dielectric portion.

17. A method for manufacturing a semiconductor memory device, comprising:
forming an interconnect structure on a semiconductor substrate, the interconnect structure including a dielectric layer and a metal line disposed in the dielectric layer;
forming a bottom electrode layer on the interconnect structure opposite to the semiconductor substrate;
forming a lower high-k dielectric layer on the bottom electrode layer opposite to the interconnect structure; and
forming a top electrode layer on the lower high-k dielectric layer opposite to the bottom electrode layer, a chemical activity of the top electrode layer with respect to an oxidation capability of a metal element included in the top electrode layer being different from a chemical activity of the bottom electrode layer with respect to an oxidation capability of a metal element included in the bottom electrode layer.

18. The method as claimed in claim 17, wherein one of the bottom electrode layer and the top electrode layer includes an inert metal, an alloy of the inert metal, a combination of the inert metal and an active metallic material, or a combination of the alloy of the inert metal and the active metallic material, and the other one of the bottom electrode layer and the top electrode layer includes the active metallic material.

19. The method as claimed in claim 18, wherein the inert metal is palladium, platinum, darmstadtium, ruthenium, molybdenum, or iridium.

20. The method as claimed in claim 18, wherein the active metallic material includes tantalum nitride, titanium nitride, tantalum, titanium, tungsten, aluminum, nickel, hafnium, lanthanum, zirconium, or combinations thereof.
